(19) United States
(12) Patent Application Publication
(10) Pub. No.: US 2019/0393403 A1
(43) Pub. Date: Dec. 26, 2019

(54) FABRICATION OF PIEZOELECTRIC TRANSDUCER INCLUDING INTEGRATED INDUCTIVE ELEMENT

(71) Applicant: Cirrus Logic International Semiconductor Ltd., Edinburgh (GB)

(72) Inventor: Anthony S. DOY, Los Gatos, CA (US)

(73) Assignee: Cirrus Logic International Semiconductor Ltd., Edinburgh (GB)

(21) Appl. No.: 16/431,383

(22) Filed: Jun. 4, 2019

Related U.S. Application Data
(60) Provisional application No. 62/689,899, filed on Jun. 26, 2018.

(51) Int. Cl. H01L 41/047; H01L 41/09

(52) U.S. Cl. CPC H01L 41/0477; H01L 41/09; H01L 41/0472

(57) ABSTRACT

A method of fabricating a device may include forming one or more conductive layers of the device to have an electrical inductance greater than that of other individual layers of conductive material of the device.

### RELATED APPLICATION

The present disclosure claims priority to U.S. Provisional Patent Application Ser. No. 62/689,899, filed Jun. 26, 2018, which is incorporated by reference herein in its entirety.

### FIELD OF DISCLOSURE

The present disclosure relates in general to a mobile device, and more particularly, to thermally protecting a capacitive load and an amplifier driving the capacitive load.

### BACKGROUND

A piezoelectric transducer may be used to generate full audio band acoustic signals by coupling the piezoelectric transducer to a suitable surface that acts as a loudspeaker. Accordingly, consumer electronic products with large display screens such as smartphones, tablets, personal computers, and televisions may benefit from adopting piezoelectric transducers as audio transducers that mechanically drive a screen. The large screen area may move a large mass of air thereby increasing loudness and bass response. As the piezoelectric transducer may be mounted behind the screen, there may be no requirement for an opening or acoustic port in the screen or body of the consumer electronic product, as is the case with traditional approaches, enabling more surface to be dedicated to display and simplifying waterproof device designs.

An amplifier architecture known as a Class D amplifier is often used to drive audio transducers in mobile devices. Class D amplifiers effectively operate by assuring a difference in output load impedance at the switching frequency versus the load impedance seen at low frequencies. In the presence of a valid output signal, a Class D amplifier output spectrum may have energy in both the audio band and switching frequency at a similar voltage level. By ensuring a lower impedance load at audio band frequency, and a correspondingly high impedance at the switching frequency, the power transferred from the Class D amplifier to the load may be translated as intended—to the audio band.

In many mobile devices using traditional coil-based audio speakers, the inherent natural impedance of such coil-based transducer usually offers a high enough impedance at the switching frequency to allow for efficient amplifier operation—no other components or external passive filters may be needed.

However, when Class D amplifiers drive capacitive loads, such as piezoelectric transducers or ceramic (e.g., including haptic) transducers, the “filterless” approach used in coil-based transducers may not provide desired output efficiency and performance. Thus, in some instances, series inductance may need to be added to increase the impedance of the capacitive load at switching frequency. For such capacitive transducers, the addition of additional wound or ferrite-based components adds considerable cost and area penalty to a mobile device. Accordingly, approaches for providing inductive elements in a compact solution are desired.

### SUMMARY

In accordance with the teachings of the present disclosure, the disadvantages and problems associated with providing inductance in a piezoelectric transducer load may be reduced or eliminated.

In accordance with embodiments of the present disclosure, a method of fabricating a device may include interleaving a plurality of layers of piezoelectric material with a plurality of conductive layers including a first conductive layer, one or more second conductive layers, and one or more third conductive layers, electrically coupling the first conductive layer to a first electrode and the one or more second conductive layers, forming the first conductive layer to have an electrical inductance between the first electrode and one of the one or more second conductive layers greater than that of individual layers of the one or more second conductive layers and the one or more third conductive layers, and electrically coupling the one or more third conductive layers to a second electrode, such that an electrical driving signal driven to the first electrode and the second electrode causes mechanical vibration of the piezoelectric transducer as a function of the electrical driving signal. The plurality of layers of piezoelectric material may electrically isolate the one or more second conductive layers from the one or more third conductive layers.

In accordance with these and other embodiments of the present disclosure, a device may include an interleaved plurality of layers of piezoelectric material with a plurality of conductive layers including a first conductive layer, one or more second conductive layers, and one or more third conductive layers, a first electrode electrically coupled to the first conductive layer and the one or more second conductive layers, and a second electrode electrically coupled to the one or more third conductive layers, such that an electrical driving signal driven to the first electrode and the second electrode causes mechanical vibration of the piezoelectric transducer as a function of the electrical driving signal. The first conductive layer may be formed to have an electrical inductance between the first electrode and one of the one or more second conductive layers greater than that of individual layers of the one or more second conductive layers and the one or more third conductive layers and the plurality of layers of piezoelectric material may electrically isolate the one or more second conductive layers from the one or more third conductive layers.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a block diagram of selected components of an example mobile device, in accordance with embodiments of the present disclosure;

FIG. 1B illustrates an exploded perspective view of selected components of an example mobile device, in accordance with embodiments of the present disclosure;

FIG. 2A illustrates a cross-sectional side elevation view of a piezoelectric transducer comprising an integrated inductive element, in accordance with embodiments of the present disclosure;

FIG. 2B illustrates a top-down plan view of a piezoelectric transducer comprising an integrated inductive element, in accordance with embodiments of the present disclosure; and

FIG. 3 illustrates a side elevation view of a piezoelectric transducer comprising two integrated inductive elements, in accordance with embodiments of the present disclosure.

### DETAILED DESCRIPTION

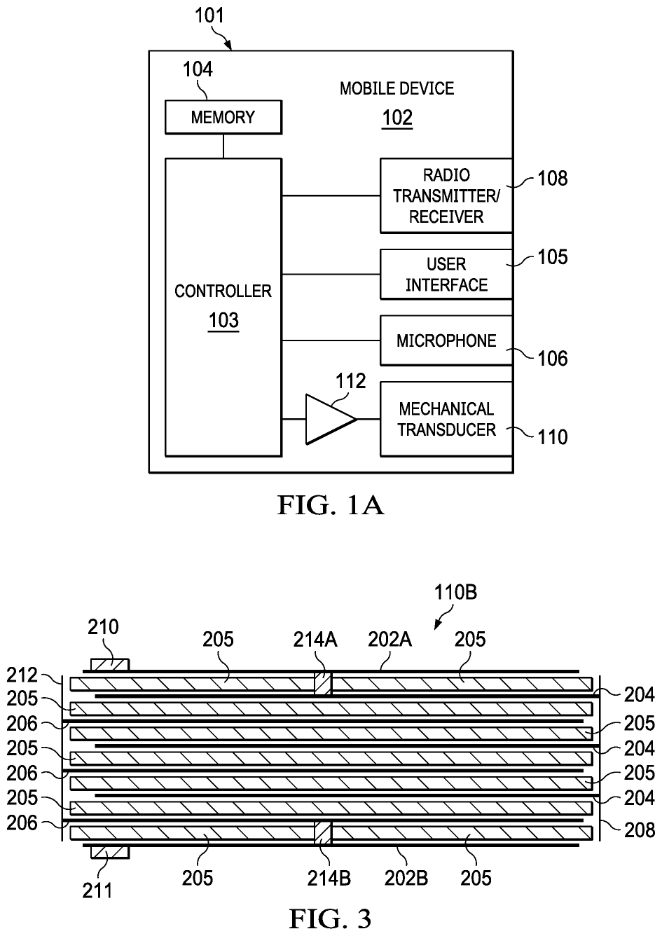

FIG. 1A illustrates a block diagram of selected components of an example mobile device 102, in accordance with embodiments of the present disclosure. As shown in FIG. 1A, mobile device 102 may comprise an enclosure 101, a controller 103, a memory 104, a user interface 105, a microphone 106, a radio transmitter/receiver 108, a mechanical transducer 110, and an amplifier 112.

Enclosure 101 may comprise any suitable housing, casing, or other enclosure for housing the various components of mobile device 102. Enclosure 101 may be constructed from plastic, metal, and/or any other suitable materials. In addition, enclosure 101 may be adapted (e.g., sized and shaped) such that mobile device 102 is readily transported on a person of a user of mobile device 102. Accordingly, mobile device 102 may include but is not limited to a smart phone, a tablet computing device, a handheld computing device, a personal digital assistant, a notebook computer, or any other device that may be readily transported on a person of a user of mobile device 102.

Controller 103 is housed within enclosure 101 and may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, controller 103 may interpret and/or execute program instructions and/or process data stored in memory 104 and/or other computer-readable media accessible to controller 103.

Memory 104 may be housed within enclosure 101, may be communicatively coupled to controller 103, and may include any system, device, or apparatus configured to retain program instructions and/or data for a period of time (e.g., computer-readable media). Memory 104 may include random access memory (RAM), electrically erasable programmable read-only memory (EEPROM), a Personal Computer Memory Card International Association (PCMCIA) card, flash memory, magnetic storage, opto-magnetic storage, or any suitable selection and/or array of volatile or non-volatile memory that retains data after power to mobile device 102 is turned off.

User interface 105 may be housed at least partially within enclosure 101, may be communicatively coupled to controller 103, and may comprise any instrumentality or aggregation of instrumentalities by which a user may interact with mobile device 102. For example, user interface 105 may permit a user to input data and/or instructions into mobile device 102 (e.g., via a keypad and/or touch screen), and/or otherwise manipulate mobile device 102 and its associated components. User interface 105 may also permit mobile device 102 to communicate data to a user, e.g., by way of a display device.

Microphone 106 may be housed at least partially within enclosure 101, may be communicatively coupled to controller 103, and may comprise any system, device, or apparatus configured to convert sound incident at microphone 106 to an electrical signal that may be processed by controller 103, wherein such sound is converted to an electrical signal using a diaphragm or membrane having an electrical capacitance that varies as based on sonic vibrations received at the diaphragm or membrane. Microphone 106 may include an electrostatic microphone, a condenser microphone, an electret microphone, a microelectromechanical systems (MEMs) microphone, or any other suitable capacitive microphone.

Radio transmitter/receiver 108 may be housed within enclosure 101, may be communicatively coupled to controller 103, and may include any system, device, or apparatus configured to, with the aid of an antenna, generate and transmit radio-frequency signals as well as receive radio-frequency signals and convert the information carried by such received signals into a form usable by controller 103. Radio transmitter/receiver 108 may be configured to transmit and/or receive various types of radio-frequency signals, including without limitation, cellular communications (e.g., 2G, 3G, 4G, LTE, etc.), short-range wireless communications (e.g., BLUETOOTH), commercial radio signals, television signals, satellite radio signals (e.g., GPS), Wireless Fidelity, etc.

Mechanical transducer 110 may be housed at least partially within enclosure 101 or may be external to enclosure 101, may be communicatively coupled to controller 103 (e.g., via amplifier 112), and may comprise any system, device, or apparatus made with one or more materials configured to generate electric potential or voltage when mechanical strain is applied to mechanical transducer 110, or conversely to undergo mechanical displacement or change in size or shape (e.g., change dimensions along a particular plane) when a voltage is applied to mechanical transducer 110. In some embodiments, a mechanical transducer may comprise a piezoelectric transducer made with one or more materials configured to, in accordance with the piezoelectric effect, generate electric potential or voltage when mechanical strain is applied to mechanical transducer 110, or conversely to undergo mechanical displacement or change in size or shape (e.g., change dimensions along a particular plane) when a voltage is applied to mechanical transducer 110.

Although specific example components are depicted above in FIG. 1A as being integral to mobile device 102 (e.g., controller 103, memory 104, user interface 105, microphone 106, radio transmitter/receiver 108, mechanical transducer 110, and amplifier 112), a mobile device 102 in accordance with this disclosure may comprise one or more components not specifically enumerated above. In addition, although controller 103 and amplifier 112 are shown as separate components in FIG. 1A, in some embodiments, controller 103 and amplifier 112 may be formed on the same integrated circuit or module.

FIG. 1B illustrates an exploded perspective view of selected components of example mobile device 102, in accordance with embodiments of the present disclosure. As shown in FIG. 1B, enclosure 101 may include a main body 120, a mechanical transducer assembly 116, and a cover assembly 130, such that when constructed, mechanical transducer assembly 116 is interfaced between main body 120 and cover assembly 130. Main body 120 may house a number of electronics, including controller 103, memory 104, radio transmitter/receiver 108, and/or microphone 106, as well as a display 122 (e.g., a liquid crystal display) of user interface 105.

Mechanical transducer assembly 116 may comprise a frame 124 configured to hold and provide mechanical structure for one or more mechanical transducers 110 (which may be coupled to controller 103) and transparent film 128.

Cover assembly 130 may comprise a frame 132 configured to hold and provide mechanical structure for cover 134. Cover 134 may be made from any suitable material (e.g., ceramic) that allows visibility through cover 134 (e.g., which may be transparent), protection of mechanical transducer 110 and display 122, and/or user interaction with display 122.

Although FIG. 1B illustrates mechanical transducer assembly 116 being situated between cover assembly 130 and display 122, in some embodiments, mechanical transducer assembly 116 may reside “behind” display 122, such that display 122 is situated between cover 130 and mechanical transducer assembly 116. In addition, although FIG. 1B illustrates mechanical transducer 110 located at particular locations within mechanical transducer assembly 116, mechanical transducer 110 may be located at any suitable location below cover 134 and/or display 122 (e.g., underneath cover 134 and/or display 122 from a perspective of a user viewing display 122).

In addition, although FIG. 1B depicts mechanical transducer 110 present within mechanical transducer assembly 116 and capable of inducing vibration on cover 130 or display 122, in some embodiments, mechanical transducer 110 may be placed proximate to main body 120 and may be capable of causing a suitable surface of main body 120 to vibrate in order to generate sound.

Although FIGS. 1A and 1B depict only a single mechanical transducer 110, mobile device 102 may include any suitable number of mechanical transducers 110.

Mechanical transducers, including piezoelectric transducers and coil-based dynamic transducers, are typically used to convert electric signals into mechanical force. Thus, when used in connection with display 122, cover 134, and/or main body 120, one or more mechanical transducers 110 may cause vibration on a surface, which in turn may produce pressure waves in air, generating human-audible sound. Accordingly, in operation of mobile device 102, one or more mechanical transducers 110 may be driven by respective amplifiers 112 under the control of controller 103 in order to generate acoustical sound by vibrating the surface of display 122, cover 134, and/or main body 120.

These types of mechanical transducers or other mechanical transducers may also be used to convey tactile responses (such as haptic effects) by being driven at frequencies which may be perceived by a person holding a device including such a mechanical transducer.

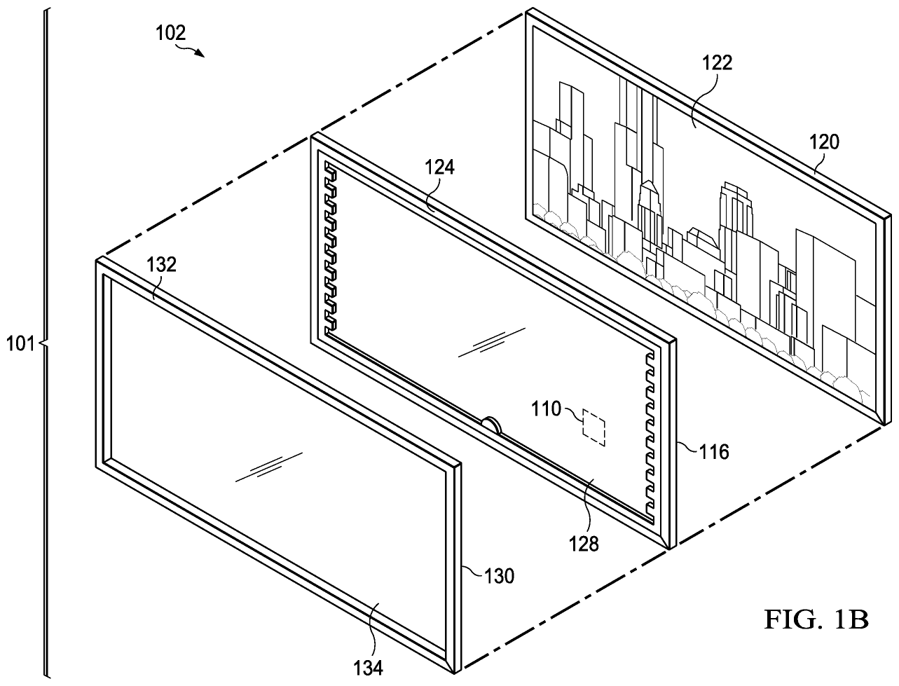

FIG. 2A illustrates a cross-sectional side elevation view of a piezoelectric transducer 110A comprising an integrated inductive element, in accordance with embodiments of the present disclosure. Conversely, FIG. 2B illustrates a top-down plan view of piezoelectric transducer 110A, in accordance with embodiments of the present disclosure. In some embodiments, piezoelectric transducer 110A may be used to implement piezoelectric transducer 110 of FIG. 1.

As shown in FIGS. 2A and 2B, piezoelectric transducer 110A may be formed by interleaving a plurality of layers of piezoelectric material 205 with a plurality of conductive layers including a first conductive layer 202, one or more second conductive layers 204, and one or more third conductive layers 206. As shown in FIG. 2B, first conductive layer 202 may be patterned in a manner (e.g., in a spiral pattern) to maximize an electrical inductance present between a first driving terminal 210 (e.g., electrode) electrically coupled to first conductive layer 202 and a via 214 that electrically couples first conductive layer 202 to a second conductive layer 204. Accordingly, first conductive layer 202 may implement an integrated inductive element as it may have an inductance greater than that of any of second conductive layers 204 and third conductive layers 206.

As shown in FIG. 2A, the one or more second conductive layers 204 may be electrically coupled to one another via a conductive termination 208, such that the one or more second conductive layers 204 are electrically coupled to first conductive layer 202 by way of via 214 and are further electrically coupled to first driving terminal 210 via first conductive layer 202. Similarly, the one or more third conductive layers 206 may be electrically coupled to one another via a conductive termination 212. Second conductive layers 204 and third conductive layers 206 may be electrically isolated from one another by layers of piezoelectric material 205, which may have dielectric properties. Conductive termination 212 may be coupled to a second driving terminal (e.g., an electrode) 211. Accordingly, an electrical driving signal driven to driving terminals 210 and 211 by an amplifier (e.g., amplifier 112) may cause mechanical vibration of piezoelectric transducer 110A as a function of the electrical driving signal, and first conductive layer 202 may implement an inductive element that is “seen” between driving terminals 210 and 211 in series with the inherent capacitance of piezoelectric transducer 110A.

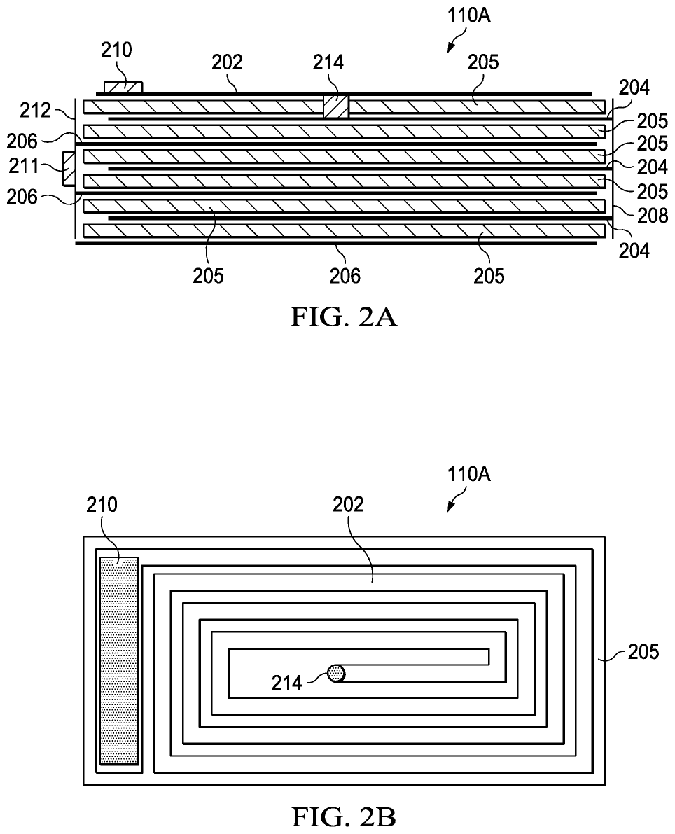

FIG. 3 illustrates a side elevation view of a piezoelectric transducer 110B comprising two integrated inductive elements, in accordance with embodiments of the present disclosure. In some embodiments, piezoelectric transducer 110B may be used to implement piezoelectric transducer 110 of FIG. 1.

As shown in FIG. 3, piezoelectric transducer 110B may be formed by interleaving a plurality of layers of piezoelectric material 205 with a plurality of conductive layers including a first conductive layer 202A, one or more second conductive layers 204, one or more third conductive layers 206, and a fourth conductive layer 202B. First conductive layer 202A and fourth conductive layer 202B may be patterned in a manner (e.g., in a spiral pattern) similar to that depicted in FIG. 2B for first conductive layer 202 in order to: (a) maximize a first electrical inductance present between a first driving terminal 210 (e.g., electrode) electrically coupled to first conductive layer 202A and a via 214A that electrically couples first conductive layer 202 to a second conductive layer 204; and (b) maximize a second electrical inductance present between a second driving terminal 211 (e.g., electrode) electrically coupled to fourth conductive layer 202B and a via 214B that electrically couples fourth conductive layer 202B to a third conductive layer 206. Accordingly, first conductive layer 202A may implement a first integrated inductive element as it may have an inductance greater than that of any of second conductive layers 204 and third conductive layers 206, and second conductive layer 202B may implement a second integrated inductive element as it may have an inductance greater than that of any of second conductive layers 204 and third conductive layers 206.

As shown in FIG. 3, the one or more second conductive layers 204 may be electrically coupled to one another via a conductive termination 208, such that the one or more second conductive layers 204 are electrically coupled to first conductive layer 202A by way of via 214A and are further electrically coupled to first driving terminal 210 via first conductive layer 202A. Similarly, the one or more third conductive layers 206 may be electrically coupled to one another via a conductive termination 212, such that the one or more third conductive layers 206 are electrically coupled to fourth conductive layer 202B by way of via 214B and are further electrically coupled to second driving terminal 211 via fourth conductive layer 202B. Second conductive layers 204 and third conductive layers 206 may be electrically isolated from one another by layers piezoelectric material 205, which may have dielectric properties. Accordingly, an electrical driving signal driven to driving terminals 210 and 211 by an amplifier (e.g., amplifier 112) may cause mechanical vibration of piezoelectric transducer 110B as a function of the electrical driving signal, and first conductive layer 202A and fourth conductive layer 202B may implement an inductive element that is “seen” between driving terminals 210 and 211 in series with the inherent capacitance of piezoelectric transducer 110A.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method of fabricating a device, comprising:
interleaving a plurality of layers of piezoelectric material with a plurality of conductive layers including a first conductive layer, one or more second conductive layers, and one or more third conductive layers;
electrically coupling the first conductive layer to a first electrode and the one or more second conductive layers;
forming the first conductive layer to have an electrical inductance between the first electrode and one of the one or more second conductive layers greater than that of individual layers of the one or more second conductive layers and the one or more third conductive layers; and
electrically coupling the one or more third conductive layers to a second electrode, such that an electrical driving signal driven to the first electrode and the second electrode causes mechanical vibration of the device as a function of the electrical driving signal;
wherein the plurality of layers of piezoelectric material electrically isolate the one or more second conductive layers from the one or more third conductive layers.

2. The method of claim 1, wherein electrically coupling the first conductive layer to the one or more second conductive layers comprises electrically coupling a via through one of the plurality of layers of piezoelectric material between the first conductive layer and one of the one or more second conductive layers.

3. The method of claim 1, comprising patterning the first conductive layer in a shape to maximize the electrical inductance.

4. The method of claim 3, wherein the shape comprises a spiral.

5. The method of claim 1, wherein:
the plurality of layers of conductive material further comprises a fourth conductive layer; and
the method further comprises:
forming the fourth conductive layer to have a second electrical inductance between the second electrode and one of the one or more third conductive layers greater than that of individual layers of the one or more second conductive layers and the one or more third conductive layers; and
electrically coupling the fourth conductive layer to the second electrode and the one or more third conductive layers.

6. The method of claim 5, wherein electrically coupling the fourth conductive layer to the one or more third conductive layers comprises electrically coupling a second via through one of the plurality of layers of piezoelectric material between the fourth conductive layer and one of the one or more third conductive layers.

7. The method of claim 5, comprising patterning the fourth conductive layer in a shape to maximize the second electrical inductance.

8. The method of claim 7, wherein the shape comprises a spiral.

9. The method of claim 1, wherein the device comprises a piezoelectric transducer.

10. A device, comprising:
an interleaved plurality of layers of piezoelectric material with a plurality of conductive layers including a first conductive layer, one or more second conductive layers, and one or more third conductive layers;
a first electrode electrically coupled to the first conductive layer and the one or more second conductive layers; and
a second electrode electrically coupled to the one or more third conductive layers, such that an electrical driving signal driven to the first electrode and the second electrode causes mechanical vibration of the device as a function of the electrical driving signal;
wherein:
the first conductive layer is formed to have an electrical inductance between the first electrode and one of the one or more second conductive layers greater than that of individual layers of the one or more second conductive layers and the one or more third conductive layers; and
the plurality of layers of piezoelectric material electrically isolate the one or more second conductive layers from the one or more third conductive layers.

11. The device of claim 10, wherein the first conductive layer and the one or more second conductive layers are electrically coupled to one another by way of a via through one of the plurality of layers of piezoelectric material between the first conductive layer and one of the one or more second conductive layers.

12. The device of claim 10, wherein the first conductive layer is patterned in a shape to maximize the electrical inductance.

13. The device of claim 12, wherein the shape comprises a spiral.

14. The device of claim 10, wherein:
the plurality of layers of conductive material further comprises a fourth conductive layer electrically coupled to the second electrode and the one or more third conductive layers; and
the fourth conductive layer is formed to have a second electrical inductance between the second electrode and one of the one or more third conductive layers greater than that of individual layers of the one or more second conductive layers and the one or more third conductive layers.

15. The device of claim 14, wherein the fourth conductive layer and the one or more third conductive layers are electrically coupled to one another by way of a second via through one of the plurality of layers of piezoelectric material between the fourth conductive layer and one of the one or more third conductive layers.

16. The device of claim 14, wherein the fourth conductive layer is patterned in a shape to maximize the second electrical inductance.

17. The device of claim 16, wherein the shape comprises a spiral.

18. The device of claim 10, wherein the device comprises a piezoelectric transducer.
